(19) United States
(12) Patent Application Publication
(10) Pub. No.: US 2006/0284653 A1
(43) Pub. Date: Dec. 21, 2006

(54) Method for sample and hold a signal and flat pannel driving method using the same

(76) Inventor: Powen Chen, Hsinchu (TW)

Correspondence Address: J C PATENTS, INC., 4 VENTURE, SUITE 250, IRVINE, CA, 92618, US

(21) Appl. No.: 11/158,145

(22) Filed: Jun. 20, 2005

(51) Int. Cl. G11C 27/02

(52) U.S. Cl. 327/95

(57) ABSTRACT

A sample-and-hold circuit is provided for an input voltage in response to a timing signal and outputting a holding voltage. The sample and hold circuit includes a plurality of switches, first and second capacitors, first and second differential input units, and an output unit. One of the switches which is controlled by a switching signal is used for preventing the voltage outputted by the output unit from being back to the inverting input terminal of the first differential input unit while the voltage of the input signal is being transferred to the first node. One of the switches which is controlled by the switching signal is used for preventing the voltage outputted by the output unit from being back to the inverting input terminal of the second differential input unit while the voltage of the input signal is being transferred to the second node.

### BACKGROUND OF THE INVENTION

1. Field of the Invention

The invention relates to a sample-and-hold circuit for an input voltage in response to a timing signal and outputting a holding voltage. More particularly, the invention relates to a sample-and-hold circuit which can be used as an analog driver application for a flat panel display.

2. Description of Related Art

A sample-and-hold circuit is arranged in the input section of an analog/digital (A/D) converter or another converting device. It samples the input voltage with prescribed timing, and then holds the sampled voltage until the end of the conversion operation by the converting device set in the next stage.

The sample and hold circuit is used, for example, for a thin-film transistor driving circuit or the like of a liquid crystal panel. FIG. 1 and FIG. 2 are circuit diagrams showing examples of constructions of conventional sample and hold circuits. The sample and hold circuit 100 shown in FIG. 1 is a circuit of the parallel 2-latch/1-buffer amplifier type disclosed in JP-B-6-54418. The circuit has an input terminal 101 to which an input voltage IN is supplied and a control terminal 102 to which a switching signal SW is supplied. Capacitors C1 and C2 for holding the input voltage IN are connected to the input terminal 101 through transmission gates (hereinafter, the transmission gate is referred to as “TG”) TG1 and TG2, respectively. The capacitors C1 and C2 are connected to the input side of a buffer amplifier (hereinafter, also referred to as “AMP”) 110 through TG3 and TG4, respectively. The output side of the AMP 110 is connected to an output terminal OUT. The switching signal SW of the control terminal 102 is supplied as a control signal to the TG1 and TG4, and inverted by an inverter 103 and then supplied as a control signal to the TG 2 and TG3.

According to such a sample and hold circuit 100, when the switching signal SW is at the “H” level, the TG1 and TG4 are turned on and the TG2 and TG3 are turned off, so that the input voltage IN at the input terminal 101 is charged into the capacitor C1 through the TG1. On the other hand, a voltage charged in the capacitor C2 is supplied to the AMP 110 through the TG4 and outputted as an output voltage OUT from the AMP 110 to the output terminal OUT.

Subsequently, when the switching signal SW is set to the “L” level, the TG1 and TG4 are turned off and the TG2 and TG3 are turned on, so that the input voltage IN at the input terminal 101 is charged into the capacitor C2 through the TG2. On the other hand, a voltage charged in the capacitor C1 is supplied to the AMP 110 through the TG3 and outputted as an output voltage OUT from the AMP 110 to the output terminal OUT.

As mentioned above, the input voltage IN is alternately charged into the two capacitors C1 and C2 in response to the switching signal SW and the charged voltage is outputted as an output voltage OUT through the AMP 110. However, this structure has a serious disadvantage and defects because CMOS switch has charge injection effect and the parasitic capacitance of AMP input transistor effect. During a period when TG3 is turned ON, the equivalent holding capacitance is C1+C_{parasitic}, but when the circuit is in a sampling phase, that is, TG3 is turned OFF, the equivalent sample capacitance is C1. Different value of capacitance between the sample phase and the hold phase accompanying with the charge injection effect when TG3 switch is turned OFF, the holding voltage will different from the input sampling voltage.

Another conventional sample and hold circuit 200 is shown in FIG. 2, which is a circuit of the parallel 2-latch/2-buffer amplifier type disclosed in JP-A-11-249633 and constructed in a manner similar to that of FIG. 2 except that the amplifier AMP 110 at the post stage of the TG3 and TG4 in FIG. 1 is deleted and amplifiers (hereinafter, also referred to as “AMPs”) 210 and 220 are provided between the capacitors C1 and C2 and the TG3 and TG4, respectively. According to such a sample and hold circuit 200, when the switching signal SW is at the “H” level, the input voltage IN at the input terminal 201 is charged into the capacitor C1 through the TG1. On the other hand, the voltage charged in the capacitor C2 is supplied to the TG4 through the AMP 220 and outputted as an output voltage to the output terminal OUT through the TG 4.

Subsequently, when the switching signal SW is set to the “L” level, the input voltage IN at the input terminal 201 is charged into the capacitor C2 through the TG2. On the other hand, the voltage charged in the capacitor C1 is supplied to the TG3 through the AMP 210 and outputted as an output voltage to the output terminal OUT through the TG 3. However, the conventional sample and hold circuit 200 has a problem of power consumption, which is a critical issue for analog type liquid crystal displays which are most used in portable devices.

A further conventional sample and hold circuit 300 is shown in FIG. 3A, which can solve the problem above by using 2 input stages and only one output stage. The sample and hold circuit 300 has an input terminal 301 to which the input voltage IN is applied and a control terminal 302 to which the switching signal SW is supplied, which is disclosed in U.S. Pat. No. 6,628,148. The input terminal 301 is connected to nodes N1 and N2 through the first switches (for example, TGs) TG1 and TG2, respectively. The capacitors C1 and C2 to hold the input voltage IN are connected between the nodes N1 and N2 and a ground GND, respectively. Non-inverting input terminals (+) of differential input units 310 and 320 are connected to the nodes N1 and N2, respectively. Each of the differential input units 310 and 320 has the same construction and outputs a voltage corresponding to a potential difference between the non-inverting input terminal and an inverting input terminal (−). For example, the differential input unit 310 has p-channel MOS transistors (hereinafter, also referred to as “PMOSs”) 312 and 314. Gates of the PMOSs 312 and 314 constructs the non-inverting input terminal and the inverting input terminal, respectively. Sources of the PMOSs 312 and 314 of each are connected to a drain of a PMOS 316. A source of the PMOS 316 is connected to a power potential VDD. A bias voltage VB is applied to a gate of the PMOS 316 so that a current flowing in the PMOS 316 is set to a constant value. Drains of the PMOSs 312 and 314 are connected to the grounding potential through an n-channel MOS transistor (hereinafter, referred to as “NMOS”) 317 and 318 respectively.

By using the sample and hold circuit 300, the power can be saved from only one output stage. But this topology has a serious problem. When the switching signal SW is at the “H” level, the TG1 and TG4 are turned on and the TG2 and TG3 are turned off, so that the output is driving by a holding voltage on the capacitor C2. Because the output voltage is different from the sampling voltage at the capacitor C1, therefore, the differential pair gate voltages are different. This will lead to a voltage spike occurs, which will couple from the parasitic capacitance C_{parasitic} to the holding capacitor C1. Then a large offset voltage occurs. FIG. 3B is a simulation result regarding the sample and hold circuit 300 of FIG. 3A. It can be seen that a larger offset voltage of output occurs due to the problem of voltage spike, especially when voltage changes large during two phase like input from 0.5V to 4.5V.

### SUMMARY OF THE INVENTION

Therefore, one object of this present invention is to provide a sample-and-hold circuit for an input voltage in response to a timing signal and outputting a holding voltage, which the problem of the voltage spike will be eliminated. That is, no offset voltage is coupled from the parasitic capacitance. The sample-and-hold circuit which can be used as an analog driver application for a flat panel display.

The above is a brief description of some deficiencies in the prior art and advantages of the present invention. Other features, advantages and embodiments of the invention will be apparent to those skilled in the art from the following description, accompanying drawings and appended claims.

### BRIEF DESCRIPTION OF THE DRAWINGS

FIG. 1 and FIG. 2 are circuit diagrams showing examples of constructions of conventional sample and hold circuits.

FIG. 3A is a further conventional sample and hold circuit.

FIG. 3B is a simulation result regarding the sample and hold circuit of FIG. 3A further conventional sample and hold circuit.

FIG. 4 is a circuit diagram of a sample and hold circuit showing a first embodiment of the invention.

FIG. 5 is a circuit diagram of a sample and hold circuit showing a second embodiment of the invention.

FIG. 6 is a circuit diagram of a sample and hold circuit showing a third embodiment of the invention.

FIG. 7(a) and 7(b) are showing an analog type liquid crystal display driving method which uses the sample and hold circuit of the present invention.

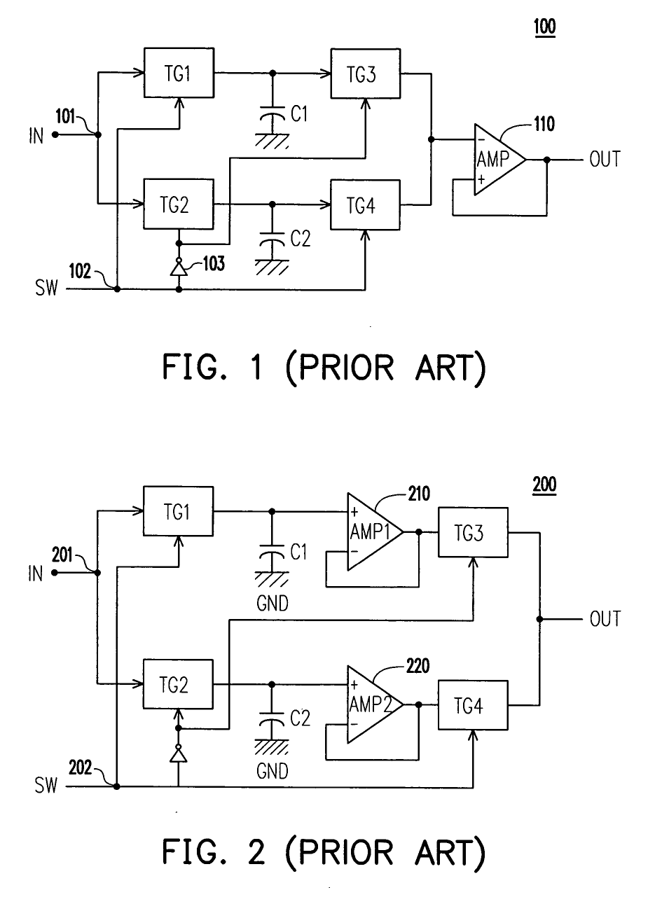

### DESCRIPTION OF THE PREFERRED EMBODIMENTS

Before describing the preferred embodiments of load-balancing method for this present invention, several terms are defined as follows.

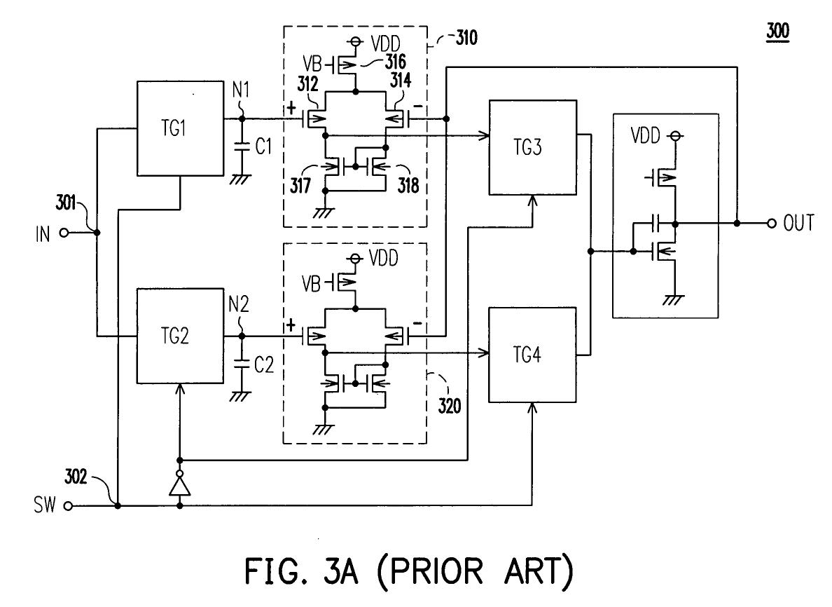

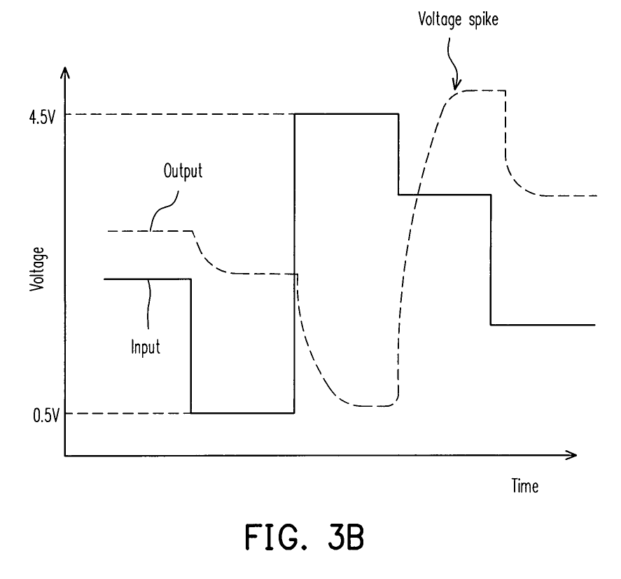

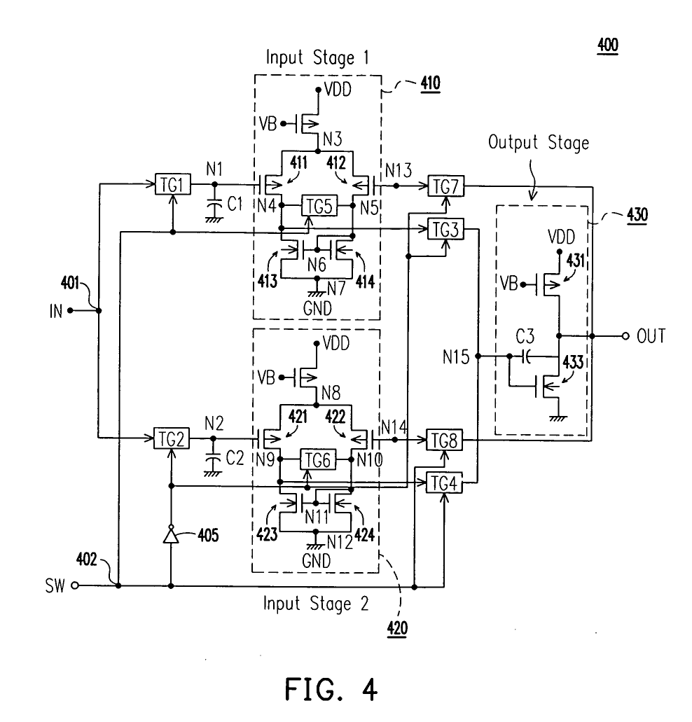

FIG. 4 is a circuit diagram of a sample and hold circuit 400 showing a first embodiment of the invention and component elements similar to those in FIG. 3 are designated by the same reference numerals. The sample and hold circuit 400 has an input terminal 401 to which an input voltage IN is applied and a control terminal 402 to which a switching signal SW is supplied. The input terminal 401 is connected to nodes N1 and N2 through switches, for example, transmission gates (hereinafter, the transmission gate is referred to as “TG”) TG1 and TG2, respectively. The capacitors C1 and C2 to hold the input voltage IN are connected between the nodes N1 and N2 and a ground GND, respectively. Non-inverting input terminals (+) of differential input units 410 and 420 are connected to the nodes N1 and N2, respectively. Each of the differential input units 410 and 420 outputs a voltage corresponding to a potential difference between the non-inverting input terminal and an inverting input terminal (−). Inverting input terminals (−) of differential input units 410 and 420 are connected to the nodes N13 and N14, respectively, as shown in FIG. 4.

For example, the differential input unit 410 has p-channel MOS (hereinafter, also referred to as “PMOS”) transistors 411 and 412. Gates of the PMOS transistors 411 and 412 constructs the non-inverting input terminal and the inverting input terminal, respectively. Sources of the PMOS transistors 411 and 412 of the differential input unit 410 are connected to a drain of a PMOS transistor 415 through a node N3. A source of the PMOS transistor 415 is connected to a power potential VDD. A bias voltage VB is applied to a gate of the PMOS 415 so that a current flowing in the PMOS transistor 415 is set to a constant value.

Drains of the PMOS transistors 411 and 412 of the differential input unit 410 are connected to the grounding potential GND through a node N4 and an n-channel MOS (hereinafter, referred to “NMOS”) transistor 413, and through a node N5 and a NMOS transistor 414, respectively. Gates of the NMOS transistors 413 and 414 are connected in common to the drain of the PMOS transistor 412. The voltage corresponding to the potential difference between the non-inverting input terminal and the inverting input terminal is outputted from the drain of the PMOS transistor 411.

In the similar structure, the differential input unit 420 has p-channel MOS (hereinafter, also referred to as “PMOS”) transistors 421 and 422. Gates of the PMOS transistors 421 and 422 constructs the non-inverting input terminal and the inverting input terminal, respectively. Sources of the PMOS transistors 421 and 422 of the differential input unit 420 are connected to a drain of a PMOS transistor 425 through a node N8. A source of the PMOS transistor 425 is connected to a power potential VDD. A bias voltage VB is applied to a gate of the PMOS transistor 425 so that a current flowing in the PMOS transistor 425 is set to a constant value.

Drains of the PMOS transistors 421 and 422 of each of the differential input unit 420 are connected to the grounding potential GND through a node N9 and n-channel MOS (hereinafter, referred to “NMOS”) transistor 423, and through a node N10 and a NMOS transistor 424, respectively. Gates of the NMOS transistors 423 and 424 are connected in common to the drain of the PMOS transistor 422. The voltage corresponding to the potential difference between the non-inverting input terminal and the inverting input terminal is outputted from the drain of the PMOS transistor 421.

Output terminals of the differential input units 410 and 420, that is, the drains of the PMOS transistors 411 and 421 are respectively connected to N15 in common through the switches (for example, TGs) TG3 and TG5, respectively. A gate of an NMOS transistor 433 of an output unit 430 is connected to the node N15. A source and a drain of the NMOS transistor 433 are connected to the grounding potential GND and output terminal OUT, respectively. A PMOS transistor 431 is connected between the output terminal OUT and power potential VDD. The bias voltage VB is applied to a gate of the PMOS transistor 431. A capacitor C3 for correcting phase characteristics is connected between the drain and the gate of the NMOS transistor 433. The transmission gates TG1 and TG4 are controlled by the switching signal SW and the transmission gates TG2 and TG3 are controlled by the inverted switching signal SW which is inverted by the an inverter 405.

In the preferred embodiment, several CMOS switches, for example, transmission gates TG5, TG6, TG7 and TG8 are incorporated in the sample and hold circuit 400. The transmission gate TG5 is incorporated between the nodes N4 and N5 and is controlled by the switching signal SW. The transmission gate TG6 is incorporated between the nodes N9 and N10 and is controlled by the inverted switching signal SW. The transmission gate TG7 is incorporated between the nodes N13, which is the inverting input terminal of the differential input unit 410, and the output terminal OUT and is controlled by the inverted switching signal SW. The transmission gate TG8 is incorporated between the nodes N14, which is the inverting input terminal of the differential input unit 420, and the output terminal OUT and is controlled by the switching signal SW.

The operation will now be described. When the switching signal SW is at the “H” level, the transmission gates TG1, TG4, TG5, TG8 are turned ON and the other transmission gates TG2, TG3, TG6 and TG7 are turned OFF. Thus, the input voltage IN applied to the input terminal 401 is charged into the capacitor C1 through the transmission gate TG1 and supplied to the non-inverting input terminal of the differential input unit 410. The capacitor C1 is in a sampling phase. Since the output voltage at the output terminal OUT is applied to the inverting input terminal of the differential input unit 410 through transmission gate TG7, which is turn OFF, the inverting input terminal of the differential input unit 410 is blocked from the output voltage from the output terminal OUT. Therefore, the voltage spike is eliminated, no offset voltage is coupled from parasitic capacitance. However, since the transmission gate TG3 is in the OFF state, it is not outputted to the node N15.

Since the transmission gate TG4 is turned on, the differential input unit 420 is connected to the output unit 430. A voltage follower circuit having a voltage amplification factor 1 is constructed by both of the units 420 and 430. Thus, the voltage charged in the capacitor C2 is generated as an output voltage to the output terminal OUT. During the sampling phase on the capacitor C1, the transmission gate TG5, which is turned on by the switch signal SW, will connect the nodes N4 and N5. The transmission gate TG7, which is turned off, will block the output voltage at the output terminal OUT being applied back to the gate of the PMOS transistor 412. Therefore, the problem of the voltage spike will be eliminated. That is, no offset voltage is coupled from the parasitic capacitance.

Subsequently, when the switching signal SW is set to “L”, the transmission gates TG1, TG4, TG5, TG8 are turned OFF and the other transmission gates TG2, TG3, TG6 and TG7 are turned ON. Thus, the input voltage IN applied to the input terminal 401 is charged into the capacitor C2 through the transmission gate TG2 and supplied to the non-inverting input terminal of the differential input unit 420. At this time, since the TG4 is in the OFF state, the input voltage IN is not outputted to the output terminal OUT. On the other hand, since the TG3 is turned on, the differential input unit 410 is connected to the output unit 430, thereby constructing a voltage follower circuit. Thus, the voltage charged in the capacitor C1 is outputted as an output voltage to the output terminal OUT.

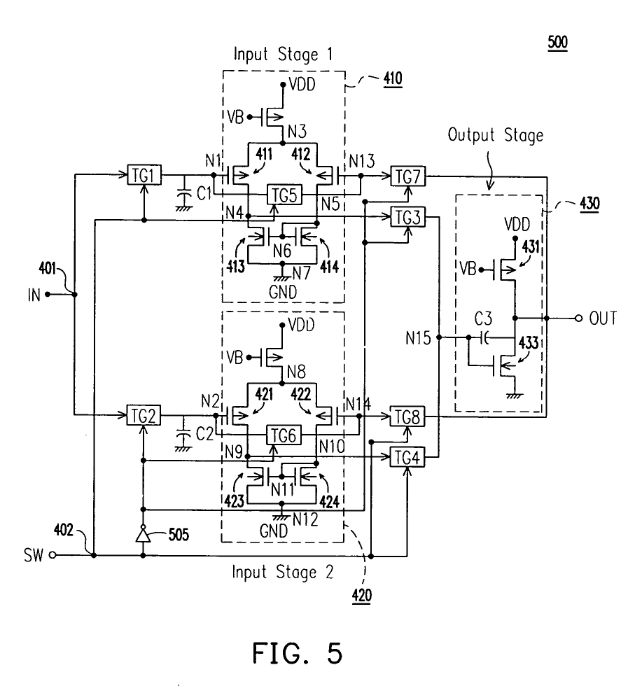

The transmission gate TG6, which is turned on by the inverted switch signal SW, will connect the nodes N9 and N1. The transmission gate TG8, which is turned off, will block the output voltage at the output terminal OUT being applied back to the gate of the PMOS transistor 422. Therefore, the problem of the voltage spike will be eliminated. That is, no offset voltage is coupled from the parasitic capacitance. FIG. 5 is a circuit diagram of a sample and hold circuit 500 showing a second embodiment of the invention and component elements similar to those in FIG. 4 are designated by the same reference numerals. The sample and hold circuit 500 has an input terminal 401 to which an input voltage IN is applied and a control terminal 402 to which a switching signal SW is supplied. The input terminal 401 is connected to nodes N1 and N2 through switches, for example, transmission gates TG1 and TG2, respectively. The capacitors C1 and C2 to hold the input voltage IN are connected between the nodes N1 and N2 and a ground GND, respectively. Non-inverting input terminals (+) of differential input units 410 and 420 are connected to the nodes N1 and N2, respectively. Each of the differential input units 410 and 420 outputs a voltage corresponding to a potential difference between the non-inverting input terminal and an inverting input terminal (−). Inverting input terminals (−) of differential input units 410 and 420 are connected to the nodes N13 and N14, respectively, as shown in FIG. 5. The structures of the differential input units 410 and 420 are similar with these as shown in FIG. 4 except for these transmission gates TG5 and TG6 incorporated in the sample and hold circuit 500.In the embodiment, the transmission gate TG5 is incorporated between the node N1, which is the non-inverting input terminal of the differential input unit 410, and the node N13, which is the inverting input terminal of the differential input unit 410, and is controlled by the switching signal SW. The transmission gate TG6 is incorporated between the node N2, which is the non-inverting input terminal of the differential input unit 420, and the node N14, which is the inverting input terminal of the differential input unit 420, and is controlled by the inverted switching signal SW.

The operation will now be described. When the switching signal SW is at the “H” level, the transmission gates TG1, TG4, TG5, TG8 are turned ON and the other transmission gates TG2, TG3, TG6 and TG7 are turned OFF. Thus, the input voltage IN applied to the input terminal 401 is charged into the capacitor C1 through the transmission gate TG1 and supplied to the non-inverting input terminal of the differential input unit 410. The capacitor C1 is in a sampling phase. Since the output voltage at the output terminal OUT is applied to the inverting input terminal of the differential input unit 410 through transmission gate TG7, which is turn OFF, the inverting input terminal of the differential input unit 410 is blocked from the output voltage from the output terminal OUT. Therefore, the voltage spike is eliminated, no offset voltage is coupled from parasitic capacitance. However, since the transmission gate TG3 is in the OFF state, it is not outputted to the node N15.

Since the transmission gate TG4 is turned on, the differential input unit 420 is connected to the output unit 430. A voltage follower circuit having a voltage amplification factor 1 is constructed by both of the units 420 and 430. Thus, the voltage charged in the capacitor C2 is generated as an output voltage to the output terminal OUT. During the sampling phase on the capacitor C1, the transmission gate TG5, which is turned on by the switch signal SW, will connect the nodes N1 and N13. That means that no voltage drop between the two ports of the transmission gate TG5, because the ideal infinite resistance seen into gates. The transmission gate TG7, which is turned off, will also block the output voltage at the output terminal OUT being applied back to the gate of the PMOS transistor 412. Therefore, the problem of the voltage spike will be eliminated. That is, no offset voltage is coupled from the parasitic capacitance.

Subsequently, when the switching signal SW is set to “L”, the transmission gates TG1, TG4, TG5, TG8 are turned OFF and the other transmission gates TG2, TG3, TG6 and TG7 are turned ON. Thus, the input voltage IN applied to the input terminal 401 is charged into the capacitor C2 through the transmission gate TG2 and supplied to the non-inverting input terminal of the differential input unit 420. At this time, since the TG4 is in the OFF state, the input voltage IN is not outputted to the output terminal OUT. On the other hand, since the TG3 is turned on, the differential input unit 410 is connected to the output unit 430, thereby constructing a voltage follower circuit. Thus, the voltage charged in the capacitor C1 is outputted as an output voltage to the output terminal OUT.

The transmission gate TG6, which is turned on by the inverted switch signal SW, will connect the nodes N2 and N14. That means that no voltage drop between the two ports of the transmission gate TG6, because the ideal infinite resistance seen into gates. The transmission gate TG8, which is turned off, will also block the output voltage at the output terminal OUT being applied back to the gate of the PMOS transistor 422. Therefore, the problem of the voltage spike will be eliminated. That is, no offset voltage is coupled from the parasitic capacitance.

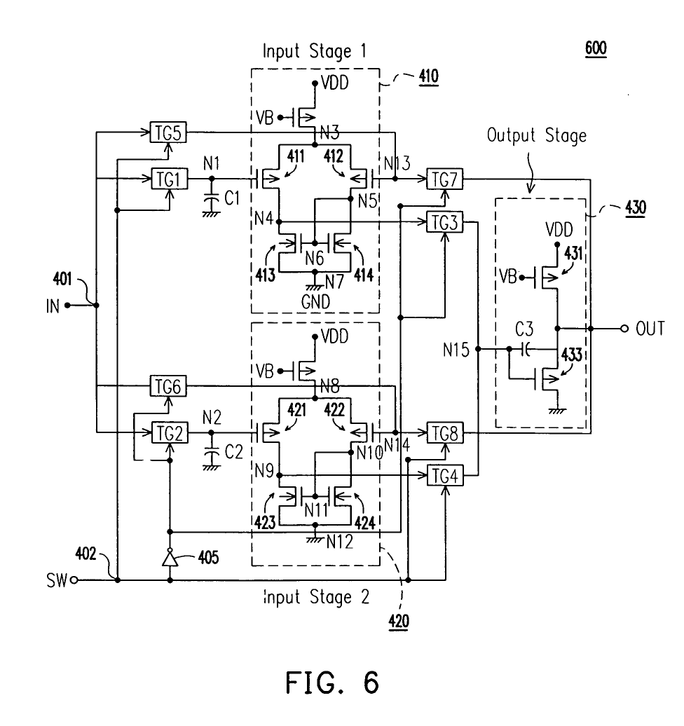

FIG. 6 is a circuit diagram of a sample and hold circuit 600 showing a third embodiment of the invention and component elements similar to those in FIG. 4 are designated by the same reference numerals. The sample and hold circuit 600 has an input terminal 401 to which an input voltage IN is applied and a control terminal 402 to which a switching signal SW is supplied. The input terminal 401 is connected to nodes N1 and N2 through switches, for example, transmission gates TG1 and TG2, respectively. The capacitors C1 and C2 to hold the input voltage IN are connected between the nodes N1 and N2 and a ground GND, respectively. Non-inverting input terminals (+) of differential input units 410 and 420 are connected to the nodes N1 and N2, respectively. Each of the differential input units 410 and 420 outputs a voltage corresponding to a potential difference between the non-inverting input terminal and an inverting input terminal (−). Inverting input terminals (−) of differential input units 410 and 420 are connected to the nodes N13 and N14, respectively, as shown in FIG. 6. The structures of the differential input units 410 and 420 are similar with these as shown in FIG. 4 except for these transmission gates TG5 and TG6 incorporated in the sample and hold circuit 600.

In the embodiment, the transmission gate TG5 is incorporated between the input terminal 401 (to another input MOS transistor) and the node N13, which is the inverting input terminal of the differential input unit 410, and is controlled by the switching signal SW. The transmission gate TG6 is incorporated between the input terminal 401 and the node N14, which is the inverting input terminal of the differential input unit 420, and is controlled by the inverted switching signal SW. The topology can avoid the charge injection which is induced from the transmission gates TG5 and TG6 as shown in the second embodiment. Because one port of the CMOS switches (for example, the transmission gates TG5 and TG6) is connected to a low impedance voltage source IN, therefore, most of the channel charges of the transmission gates TG5 and TG6 will inject into low impedance voltage source IN. A more correct voltage is outputted from the sample and hold circuit 600 to, for example, the panel loading of a flat panel display.

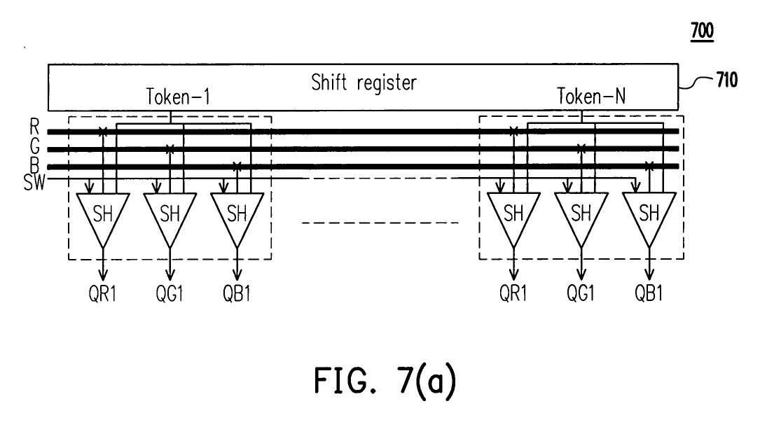

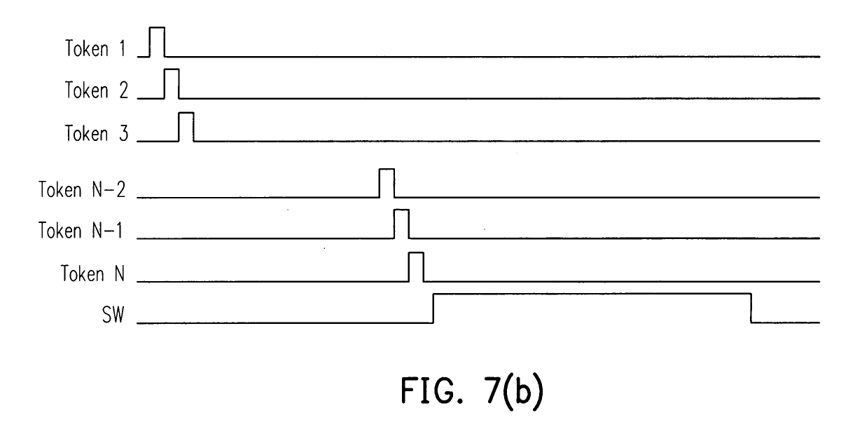

FIG. 7(a) and 7(b) are showing an analog type liquid crystal display driving method which uses the sample and hold circuit of the present invention. A plurality of sample and hold circuits (which is denoted as “SH” in FIG. 7(a)) of the present invention are connected to R, G, B analog signal inputs and a switch signal SW. Token as a sampling phase, which is controlled by the shift register 710, the switch signal SW control switch two input stages, including the sampling phase and the holing phase. As shown in FIG. 7(b), a plurality of tokens, from token 1 to token n in the shift register 710, are sequentially activated for sampling in the driving method.

The above description provides a full and complete description of the preferred embodiments of the present invention. Various modifications, alternate construction, and equivalent may be made by those skilled in the art without changing the scope or spirit of the invention. Accordingly, the above description and illustrations should not be construed as limiting the scope of the invention which is defined by the following claims.

What is claimed is:

1. A sample and hold circuit comprising:
a first switch connected between an input terminal and a first node, the input terminal receiving an input signal, the first switch being controlled by a switching signal having alternating first and second states and alternately transferring the voltage of the input signal to the first node as the states alternate;
a second switch connected between the input terminal and a second node, the second switch being controlled by the switching signal having alternative first and second states and alternately transferring the voltage of the input signal to the second node as the states alternate;
first and second capacitors which hold the voltage of the input signal transferred to the first and second nodes, respectively;
a first differential input unit comprising an inverting input terminal and a non-inverting input terminal, the non-inverting input terminal being coupled to the first node, the first differential input unit for generating a first voltage corresponding to a potential difference between the first node and the inverting input terminal;
a second differential input unit comprising an inverting input terminal and a non-inverting input terminal, the non-inverting input terminal being coupled to the second node, the second differential input unit for generating a second voltage corresponding to a potential difference between the second node and the inverting input terminal;
a pair of third switches which are controlled by the switching signal, for transferring the second voltage generated by the second differential input unit to a third node while the voltage of the input signal is being transferred to the first node, and for transferring the first voltage generated by the first differential input unit to the third node while the voltage of the input signal is being transferred to the second node;
an output unit which outputs a voltage corresponding to the voltage at the third node to the output terminal;
a fourth switch which is controlled by the switching signal, incorporated between the output terminal and the inverting input terminal of the first differential input unit for preventing the voltage outputted by the output unit from being back to the inverting input terminal of the first differential input unit while the voltage of the input signal is being transferred to the first node; and
a fifth switch which is controlled by the switching signal, incorporated between the output terminal and the inverting input terminal of the second differential input unit for preventing the voltage outputted by the output unit from being back to the inverting input terminal of the second differential input unit while the voltage of the input signal is being transferred to the second node.

2. The sample and hold circuit of claim 1, wherein the first differential input unit comprising a first differential pair of transistors, a first constant current source that continuously supplies a first constant current to the first differential pair of transistors, and a first current mirror circuit which continuously sinks the first constant current after passage thereof through the first differential pair of transistors, one of the transistors of the first differential pair being connected to the first current mirror circuit at a first connection point, the voltage corresponding to the potential difference between the first node and the inverting input terminal of the first differential input unit continuously appearing at the first connection point.

3. The sample and hold circuit of claim 2, wherein a sixth switch is incorporated between the first connection point and a second connection point at which the other one of the transistors of the first differential pair is connected to the first current mirror circuit other than the first connection point.

4. The sample and hold circuit of claim 3, wherein the sixth switch is controlled by the switching signal and while the voltage of the input signal is being transferred to the first node, the sixth switch connects the first connection point and the second connection point.

5. The sample and hold circuit of claim 1, wherein a seventh switch is incorporated between the first node and the inverting input terminal of the first differential input unit.

6. The sample and hold circuit of claim 5, wherein the seventh switch is controlled by the switching signal and while the voltage of the input signal is being transferred to the first node, the seventh switch connects the first node and the inverting input terminal of the first differential input unit.

7. The sample and hold circuit of claim 1, wherein the second differential input unit comprising a second differential pair of transistors, a second constant current source that continuously supplies a second constant current to the second differential pair of transistors, and a second current mirror circuit which continuously sinks the second constant current after passage thereof through the second differential pair of transistors, one of the transistors of the second differential pair being connected to the second current mirror circuit at a third connection point, the voltage corresponding to the potential difference between the second node and the inverting input terminal of the second differential input unit continuously appearing at the third connection point.

8. The sample and hold circuit of claim 7, wherein a eighth switch is incorporated between the third connection point and a fourth connection point at which the other one of the transistors of the second differential pair is connected to the first current mirror circuit other than the third connection point.

9. The sample and hold circuit of claim 8, wherein the eighth switch is controlled by the switching signal and while the voltage of the input signal is being transferred to the second node, the eighth switch connects the third connection point and the fourth connection point.

10. The sample and hold circuit of claim 1, wherein a ninth switch is incorporated between the second node and the inverting input terminal of the second differential input unit.

11. The sample and hold circuit of claim 10, wherein the ninth switch is controlled by the switching signal and while the voltage of the input signal is being transferred to the second node, the ninth switch connects the second node and the inverting input terminal of the second differential input unit.

12. The sample and hold circuit of claim 1, wherein a tenth switch is incorporated between the input terminal and the inverting input terminal of the first differential input unit.

13. The sample and hold circuit of claim 12, wherein the tenth switch is controlled by the switching signal and while the voltage of the input signal is being transferred to the first node, the tenth switch connects the input terminal and the inverting input terminal of the first differential input unit.

14. The sample and hold circuit of claim 1, wherein a eleventh switch is incorporated between the input terminal and the inverting input terminal of the second differential input unit.

15. The sample and hold circuit of claim 14, wherein the eleventh switch is controlled by the switching signal and while the voltage of the input signal is being transferred to the second node, the eleventh switch connects the input terminal and the inverting input terminal of the second differential input unit.

16. The sample and hold circuit of claim 1, wherein the output unit constructs a buffer amplifier together with each of the differential input units.

17. The sample and hold circuit of claim 1, wherein each of the capacitors is a sample holding capacitor for holding a sampled signal.
